(19) United States
(12) Patent Application Publication
(10) Pub. No.: US 2025/0323140 A1
(43) Pub. Date: Oct. 16, 2025

(54) BACKSIDE CAPACITOR FOR REDUCING POWER DELIVERY NETWORK IMPEDANCE

(71) Applicant: Marvell Asia Pte Ltd, Singapore (SG)

(72) Inventors: Zachary Baldwin, Burlington, VT (US); Ting Zheng, San Jose, CA (US); Carlos Macian Ruiz, Los Gatos, CA (US); Kazin Simon Blacklow, Burlington, VT (US); Joshua F. Dillon, Stowe, VT (US); Wolfgang Sauter, Starksboro, VT (US); John Edward Gregory, JR., Dummerston, VT (US); Samer Akiki, Redwood City, CA (US)

(21) Appl. No.: 19/176,000

(22) Filed: Apr. 10, 2025

Related U.S. Application Data
(60) Provisional application No. 63/633,036, filed on Apr. 11, 2024.

(51) Int. Cl. H01L 23/522; H01L 21/768; H01L 23/48; H10D 1/00; H10D 1/68

(52) U.S. Cl. CPC H01L 23/5222; H01L 21/76898; H01L 23/481; H10D 1/043; H10D 1/714; H10D 1/716

(57) ABSTRACT

A die has an integrated circuit with backside decoupling capacitance that reduces impact of noise caused by a power delivery network supplying power to the integrated circuit. The integrated circuit includes a power delivery network spanning a front end of line region, a back end of line region, and a backside region. The integrated circuit includes a decoupling capacitor disposed in the backside region to provide a backside decoupling capacitance. The decoupling capacitor includes at least two respective portions of at least two of backside metal traces such that each of the at least two respective portions are electrically coupled to at least one of the front end of line region or the back end of line region by at least two respective through-silicon vias among the plurality of through-silicon vias, and a dielectric material is arranged between the at least two respective portions of the backside metal traces.

### CROSS REFERENCE TO RELATED APPLICATION

This disclosure claims the benefit of copending, commonly-assigned U.S. Provisional Patent Application No. 63/633,036, filed Apr. 11, 2024, which is hereby incorporated by reference herein in its entirety.

### FIELD OF USE

This disclosure relates to reducing power delivery network impedance in a power delivery network of an integrated circuit. More particularly, this disclosure relates to the use of a backside capacitor to provide a decoupling capacitance that reduces the power delivery network impedance.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the subject matter of the present disclosure.

A power delivery network distributes power through a die to components of an integrated circuit fabricated in the die. Increasing power requirements of integrated circuits increases the sensitivity of these circuits to power supply voltage fluctuations. Reducing the magnitude of power supply voltage fluctuations, and other detriments caused by power delivery network impedance, increases the performance capabilities of an integrated circuit. Capacitors can be used to provide decoupling capacitances that reduce power delivery network impedance, but providing relatively large decoupling capacitances requires allocation of relatively large portions of the die.

### SUMMARY

In accordance with implementations of the subject matter of this disclosure, a die has an integrated circuit with backside decoupling capacitance that reduces impact of noise caused by a power delivery network supplying power to the integrated circuit. The die has a front end of line region including active silicon devices, a back end of line region, and a backside region opposite the back end of line region. The integrated circuit includes a power delivery network spanning the front end of line region, the back end of line region, and the backside region. The power delivery network includes a plurality of through-silicon vias disposed perpendicular to the plurality of lateral metal traces and configured to provide electrical connections between the front end of line region, the back end of line region, and the backside region. The plurality of through-silicon vias is electrically coupled to a plurality of lateral metal traces including back end of line metal traces disposed in the back end of line region and backside metal traces disposed in the backside region. The integrated circuit further includes a decoupling capacitor disposed in the backside region to provide the backside decoupling capacitance. The decoupling capacitor includes at least two respective portions of at least two of the backside metal traces, such that each of the at least two respective portions are electrically coupled to at least one of the front end of line region or the back end of line region by at least two respective through-silicon vias among the plurality of through-silicon vias. A dielectric material is arranged between the at least two respective portions of the backside metal traces.

In a first implementation of such a die, the dielectric material and the at least two respective portions of the at least two of the backside metal traces are interdigitated to increase a contact surface area between the dielectric material and the at least two respective portions of the at least two of the backside metal traces such that the increased contact surface area increases capacitance of the decoupling capacitor.

In a second implementation of such a die, the back end of line region includes a plurality of interconnects which electrically couple the integrated circuit to a redistribution layer or a bond pad layer.

In a first aspect of that second implementation, at least one interconnect of the plurality of interconnects is further electrically coupled to a second backside region of a second die to reduce impact of noise caused by a second power delivery network of the second die.

In a second aspect of that second implementation, at least one interconnect of the plurality of interconnects is further electrically coupled to a second back end of line region of a second die to reduce impact of noise caused by a second power delivery network of the second die.

In a third implementation of such a die, the backside metal traces include first metal traces, second metal traces stacked on top of the first metal traces, third metal traces stacked on top of the second metal traces, and fourth metal traces stacked on top of the third metal traces. Respective portions of the first metal traces, the second metal traces, the third metal traces, and the fourth metal traces are interdigitated with each other.

In a first aspect of that third implementation, the dielectric material includes a first layer disposed in between respective interdigitated portions of the first metal traces and the second metal traces, a second layer disposed in between respective interdigitated portions of the second metal traces and the third metal traces, and a third layer disposed in between respective interdigitated portions of the third metal traces and the fourth metal traces.

In a second aspect of that third implementation, at least one first through-silicon via among the plurality of through-silicon vias is coupled to the first metal traces and to the third metal traces to form a first plate of the decoupling capacitor, and at least one second through-silicon via among the plurality of through-silicon vias is coupled to the second metal traces and to the fourth metal traces to form a second plate of the decoupling capacitor.

In a fourth implementation of such a die, the decoupling capacitor is a first decoupling capacitor, and the die further includes a second decoupling capacitor disposed in the backside region.

In a first aspect of that fourth implementation, the first decoupling capacitor is coupled to a global power network that is coupled to a first supply voltage that is utilized by a majority of circuitry of the integrated circuit, and the second decoupling capacitor is coupled to a local power network that is coupled to a second supply voltage that is utilized by at least one circuit in the integrated circuit that is not coupled to the first supply voltage.

In accordance with implementations of the subject matter of this disclosure, a method for reducing impact of noise caused by a power delivery network supplying power to a die having an integrated circuit is provided. The die has a front end of line region including active silicon devices, a back end of line region, and a backside region opposite the back end of line region. The method includes arranging a plurality of through-silicon vias to provide a plurality of electrical connections between the front end of line region, the back end of line region, and the backside region. The method includes disposing a decoupling capacitor in the backside region to provide a decoupling capacitance for the power delivery network. The decoupling capacitor has a dielectric material arranged between at least two respective portions of two backside metal traces. The method includes arranging at least two respective through-silicon vias among the plurality of through-silicon vias to provide electrical connections between each of the at least two respective portions of the two backside metal traces and at least one of the front end of line region or the back end of line region.

A first implementation of such a method may further include interdigitating the dielectric material and the at least two respective portions of the at least two of the backside metal traces to increase a contact surface area between the dielectric material and the at least two respective portions of the at least two of the backside metal traces such that the increased contact surface area increases capacitance of the decoupling capacitor.

In a second implementation of such a method, the back end of line region includes a plurality of interconnects, and the method may further include electrically coupling the integrated circuit to a redistribution layer or a bond pad layer using the plurality of interconnects.

In a first aspect of that second implementation, such a method may further include electrically coupling a second backside region of a second die to at least one interconnect of the plurality of interconnects to reduce impact of noise caused by a second power delivery network of the second die.

In a second aspect of that second implementation, such a method may further include electrically coupling a second back end of line region of a second die to at least one interconnect of the plurality of interconnects to reduce impact of noise caused by a second power delivery network of the second die.

In a third implementation of such a method, the backside metal traces include first metal traces, second metal traces stacked on top of the first metal traces, third metal traces stacked on top of the second metal traces, and fourth metal traces stacked on top of the third metal traces, and such a method may further include interdigitating respective portions of the first metal traces, the second metal traces, the third metal traces, and the fourth metal traces with each other.

In a first aspect of that third implementation, such a method may further include disposing a first layer of dielectric material in between respective interdigitated portions of the first metal traces and the second metal traces, disposing a second layer of dielectric material in between respective interdigitated portions of the second metal traces and the third metal traces, and disposing a third layer of dielectric material in between respective interdigitated portions of the third metal traces and the fourth metal traces.

In a second aspect of that third implementation, such a method may further include electrically coupling at least one first through-silicon via among the plurality of through-silicon vias to the first metal traces and to the third metal traces to form a first plate of the decoupling capacitor and electrically coupling at least one second through-silicon via among the plurality of through-silicon vias to the second metal traces and to the fourth metal traces to form a second plate of the decoupling capacitor.

In a fourth implementation of such a method, the decoupling capacitor is a first decoupling capacitor, and the die further includes a second decoupling capacitor disposed in the backside region. Such a method further includes electrically coupling the first decoupling capacitor a global power network, electrically coupling the global power network to a first supply voltage that is utilized by a majority of circuitry of the integrated circuit, electrically coupling the second decoupling capacitor to a local power network, and electrically coupling the local power network to a second supply voltage that is utilized by at least one circuit in the integrated circuit that is not coupled to the first supply voltage.

In accordance with implementations of the subject matter of this disclosure, a die has a back end of line region, a front end of line region, a backside region opposite to the back end of line region, a power delivery network supplying power to the die, and a backside capacitor configured to reduce impact of noise caused by the power delivery network. The backside capacitor includes at least two respective portions of at least two backside metal traces disposed in the backside region, and a dielectric material disposed in between the at least two respective portions of the at least two backside metal traces, such that each of the at least two respective portions of the at least two backside metal traces are electrically coupled, by at least one respective through-silicon via, to the front end of line region to reduce the impact of the noise caused by the power delivery network on active silicon devices of the front end of line region.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 is an illustrative cross-sectional view of a die including an integrated circuit with a backside capacitor, in accordance with one implementation of the subject matter of this disclosure;

FIG. 2 is an illustrative cross-sectional view of a die including an integrated circuit with a backside metal capacitor having interdigitated metal plates, in accordance with one implementation of the subject matter of this disclosure;

FIG. 3 is an illustrative cross-sectional view of a die including an integrated circuit with a backside capacitor spanning four metal traces, in accordance with one implementation of the subject matter of this disclosure;

FIG. 4 shows an illustrative plan view of a power delivery network having global and local power networks, and an illustrative cross-sectional view of separate backside capacitors for the global and local power networks, in accordance with one implementation of the subject matter of this disclosure;

FIG. 5 is an illustrative cross-sectional view of a backside capacitor providing a decoupling capacitance for two dies stacked using face-to-back bonding, in accordance with one implementation of the subject matter of this disclosure;

FIG. 6 is an illustrative cross-sectional view of a backside capacitor providing a decoupling capacitance for two dies stacked using face-to-face bonding, in accordance with one implementation of the subject matter of this disclosure; and

FIG. 7 is a flow diagram illustrating a method for reducing impact of noise caused by a power delivery network supplying power to a die having an integrated circuit, in accordance with one implementation of the subject matter of this disclosure.

### DETAILED DESCRIPTION

Application specific integrated circuits (ASICs), such as those used in artificial intelligence workflows, can require large power consumption. A power delivery network, made of physical traces and planes, delivers power to the components of an ASIC. As such, a well-designed power delivery network can efficiently supply power to an ASIC and thereby can support the performance of the ASIC.

However, a power delivery network inevitably contributes electrical impedance, which can reduce the quality of power delivery and cause other detrimental effects. For example, voltage fluctuations and power noise caused by power delivery network impedance may prevent an ASIC from meeting its maximum performance specifications. To reduce power delivery network impedance and thereby support the robustness of a corresponding ASIC, a decoupling capacitor providing a decoupling capacitance may be connected to the power delivery network.

A decoupling capacitor may provide a decoupling capacitance to reduce power delivery network impedance. Ideally, the decoupling capacitor should be located as close as possible to the integrated circuit components consuming power. However, dies have limited space to allocate to decoupling capacitors, which require a relatively large amount of space to provide a relatively large capacitance.

In some implementations, a decoupling capacitor may be disposed in the dielectric layer of a silicon interposer (e.g., which is electrically coupled to an integrated circuit die). However, due to the limited space in the dielectric layer, such implementations may not sufficiently reduce power delivery network impedance (e.g., for high-power and high-frequency applications). In other implementations, a decoupling capacitor may be coplanar with through-silicon vias embedded in an interposer. However, such implementations may present limited space to allocate to the capacitor and may cause those capacitors to be degraded by thermal stress incurred by heating of the nearby through-silicon vias. In both of those interposer-based implementations, providing the decoupling capacitor in the interposer limits the capacitor's proximity to active silicon devices of an integrated circuit.

In accordance with implementations of the subject matter of this disclosure, a decoupling capacitor is disposed in the backside region of a die (and is hereafter referred to as a backside capacitor) to provide a decoupling capacitance for components of the die (e.g., active silicon devices of an integrated circuit fabricated in the die). As used herein, the backside region of die refers to the region of the die that is formed during backside metallization, opposite to the back end of line region of the die, which includes wiring and interconnects. Between the backside region and the back end of line region is the front end of line region, which includes active silicon devices.

The backside region of a die is typically used to dispose interconnects and connective wirings. By fabricating the decoupling capacitor into the backside region, a relatively large capacitor size and close capacitor proximity to functional circuitry can be achieved. The backside capacitor is arranged to be in direct electrical contact, within the same die, as planes and/or traces of a power delivery network, thereby improving the effectiveness of how this decoupling capacitance reduces power delivery network impedance. In some implementations, multiple dies are stacked, and the backside capacitor (though only being disposed in one of the multiple stacked dies) can provide decoupling capacitance to at least two dies.

In accordance with implementations of the subject matter of this disclosure, a method for reducing impact of noise caused by a power delivery network supplying power to a die having an integrated circuit is provided. A die includes a front end of line region (which includes active silicon devices), a back end of line region, and a backside region opposite to the back end of line region. The integrated circuit includes a power delivery network spanning the front end of line region, back end of line region, and the backside region. A decoupling capacitor is disposed in the backside region (i.e., a backside capacitor) and a dielectric material is arranged between at least two metal layers of the decoupling capacitor to provide the decoupling capacitance. For example, a dielectric material may be disposed in between a first backside metal layer and second backside metal layer to form the decoupling capacitor. Respective through-silicon vias may extend from those first and second backside metal layers to electrically couple the backside capacitor to any suitable components of the front end of line and/or back end of line regions of the integrated circuit.

In some implementations, the structure of the backside capacitor may be interdigitated to increase the surface area and therefore the capacitance. As further described below, the structure may be interdigitated when using two metal traces, or it may be interdigitated by using more than two metal traces. In some implementations, multiple backside capacitors may be included to provide respective capacitances for various portions of an integrated circuit (e.g., a first capacitance for a global power network and a second capacitance for a local power network).

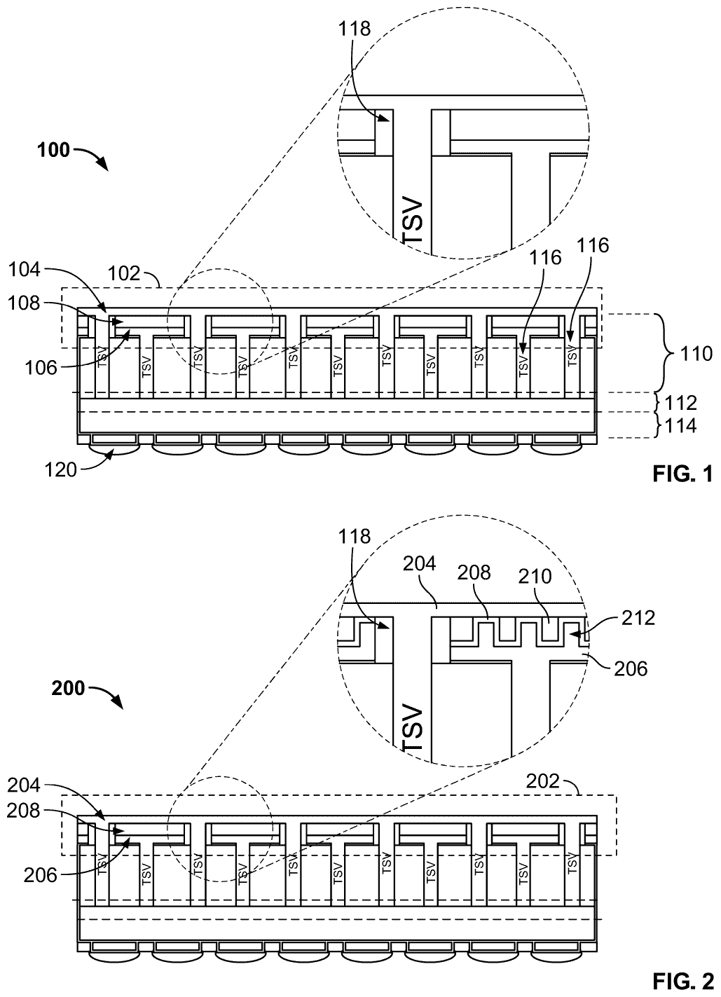

The subject matter of this disclosure is further described below with reference to FIGS. 1-7.

FIG. 1 is an illustrative cross-sectional view of die 100 including backside capacitor 102, in accordance with one implementation of the subject matter of this disclosure. As mentioned above, backside capacitor 102 is described as such because it is disposed in backside region 110 of die 100. As shown, backside region 110 is opposite to back end of line region 114 and front end of line region 112 is between backside region 110 and back end of line region 114.

Backside capacitor 102 is coupled to at least one portion of front end of line region 112 or back end of line region 114 by at least two through-silicon vias 116 (e.g., where through-silicon vias 116 includes at least one first though-silicon via coupled to a first plate of backside capacitor 102 and at least one second though-silicon via coupled to a second plate of backside capacitor 102). To maintain electrical isolation of the various components of the backside capacitor 102, any suitable insulating material 118 may be arranged adjacent to respective portions of the plurality of through-silicon vias 116 traversing the backside region, as shown in FIG. 1.

Disposing backside capacitor 102 in backside region 110 utilizes space on die 100 to provide decoupling capacitance. This decoupling capacitance reduces the power delivery network impedance, thereby supporting the performance of an ASIC, or any other suitable integrated circuit, that is fabricated into die 100.

As shown in FIG. 1, die 100 includes an ASIC including front end of line region 112 and back end of line region 114. Front end of line region 112 includes active silicon devices, as well as any other passive silicon devices or electrical connections. Back end of line region 114 includes interconnects (which are not shown in the illustration of FIG. 1) that couple the ASIC to a redistribution layer or bond pad layer (e.g., bump layer 120). Backside capacitor 102 reduces the impedance of the power delivery network supplying power across the ASIC. The power delivery network spans backside region 110, front end of line region 112, and back end of line region 114. The power delivery network is electrically coupled to a first set of lateral metal traces disposed in backside region 110 and a second set of lateral metal traces disposed in back end of line region 114.

Die 100 includes a plurality of through-silicon vias 116. Each through-silicon via of the plurality of through-silicon vias 116 is arranged perpendicular to the first set of lateral metal traces of backside region 110 and the second set of lateral metal traces of back end of line region 114. This arrangement configures the power delivery network to provide power to front end of line region 112.

As described above, power delivery network impedance may hinder the reliability of an ASIC or any other component to which the network supplies power. Disposing backside capacitor 102 in backside region 110 provides a significant decoupling capacitance proximal to the ASIC of die 100. That is, the backside decoupling capacitance does not have to be off-chip. The proximity of the backside decoupling capacitance may increase its effectiveness at reducing power delivery network impedance, e.g., compared to an off-chip solution. Backside capacitor 102 includes at least metal traces 104, metal traces 106, and dielectric material 108. Dielectric material 108 is arranged between at least metal traces 104 and metal traces 106. The first set of lateral metal traces of backside region 110 includes metal traces 104 and 106. Metal traces 104 and 106 are part of lateral metal traces that are part of back end of line region 114. Metal traces 104 and metal traces 106 may each be

coupled to one or more respective through-silicon vias 116. Through-silicon vias 116 electrically couple respective plates of the backside capacitor 102 to front end of line region 112 (effectively bringing the decoupling capacitance even more proximal to the active silicon devices). At least two through-silicon vias are needed to couple backside capacitor 102 to front end of line region 112. For example, at least one through-silicon via of through-silicon vias 116 is needed to couple metal traces 104 to front end of line region 112, and at least one through-silicon via of through-silicon vias 116 is needed to couple metal traces 106 to front end of line region 112. As shown in FIG. 1, multiple through-silicon vias 116 may be disposed in die 100 to couple backside capacitor 102 to various portions of front end of line region 112.

Metal traces 104 and 106 may be disposed in respective metal layers. Metal traces 104 and 106 may span a portion of the metal layer, or possibly the entire metal layer that is deposited during die fabrication.

Rather than being flat metal traces, as shown in FIG. 1, metal traces 104 and 106 may be fabricated in an interdigitated manner that further increases the backside capacitance by increasing the contact surface area between those metal traces and the intervening dielectric material 108. FIG. 2 is an illustrative cross-sectional view of a die including an integrated circuit with a backside capacitor having interdigitated metal plates, in accordance with one implementation of the subject matter of this disclosure.

Die 200 may correspond to die 100, except that metal traces 104 and 106, as well as dielectric layer 108, are modified to be interdigitated, rather than flat. Backside capacitor 202 of die 200 includes metal traces 204 and metal traces 206. As shown, the interdigitating of metal traces 204 and 206 results in interlocking structures resembling fingers, to increase the capacitor surface area relative to flat plates (e.g., as shown in FIG. 1). For example, metal traces 204 and 206 may include supplemental metal structures 210 and 212, respectively, which are interdigitated around similarly structured dielectric traces 208. Interdigitated structures 210 are part of metal traces 204, and interdigitated structures 212 are part of metal traces 206. Metal traces 204 and metal traces 206 may each span one respective metal layer, or they may span more than one respective metal fabrication layer; that is, the metal structures 210 and 212 may be disposed on separate metal layers from those of traces 204 and 206 (e.g., with intervening metal connections), or they may be disposed on the same metal layers as traces 204 and 206 (e.g., with varying metal layer thickness for interdigitating purposes, as shown).

The geometry of interdigitated structures 210 and 212, as depicted in FIG. 2, is merely illustrative of one possible implementation. Other types of structures may result from different fabrication processes of metal traces 204 and 206. For example, interdigitated structures 210 or 212 may be more rounded, form jagged points, or otherwise form any suitable shape that increases the contact surface area between dielectric layer 208 and surrounding conductive material.

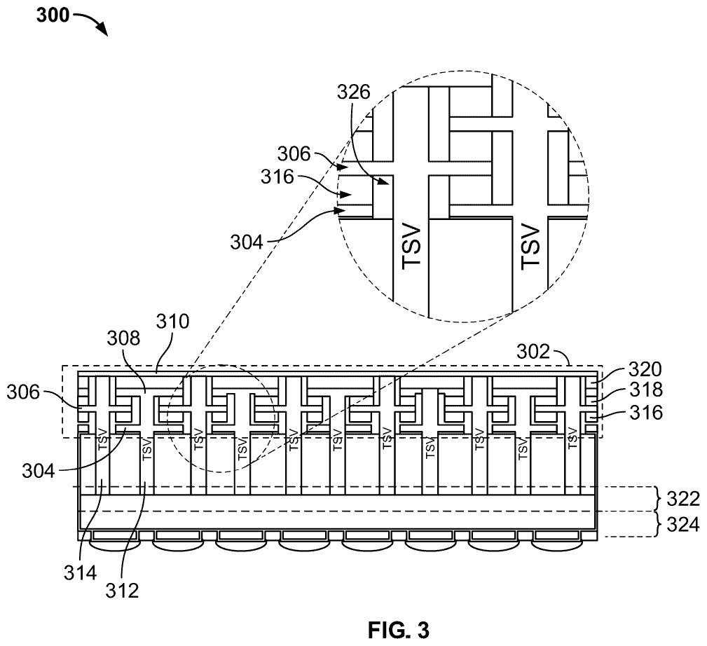

Another approach to forming a backside capacitor with interdigitated structures is shown in FIG. 3. In the approach of FIG. 3, backside capacitor 302 includes multiple metal traces (e.g., including traces from more than two metal layers) to further increase its decoupling capacitance. FIG. 3 shows an illustrative cross-sectional view of a die including an integrated circuit with a backside capacitor spanning four metal layers, in accordance with one implementation of the subject matter of this disclosure.

Die 300 may correspond to die 100 or die 200, except die 300 includes backside capacitor 302 made of four metal traces (e.g., first metal traces 304, second metal traces 306, third metal traces 308, and fourth metal traces 310). Respective portions of second metal traces 306, third metal traces 308, and fourth metal traces 310 may be interdigitated with respect to each other, as shown, to increase the capacitance of backside capacitor 302. In some implementations, first metal traces 304, second metal traces 306, third metal traces 308, and fourth metal traces 310 correspond to first, second, third, and fourth metal layers, respectively.

The two plates of backside capacitor 302 are each formed by two respective metal traces that are electrically coupled to each other using respective through-silicon vias. Specifically, a first plate of backside capacitor 302 is formed by through-silicon vias 312 being coupled to first metal traces 304 and third metal traces 308. A second plate of backside capacitor 302 is formed by through-silicon vias 314 being coupled to second metal traces 306 and fourth metal traces 310. In addition to electrically coupling discrete backside metal traces, through-silicon vias 312 and 314 electrically couple the plates of backside capacitor 302 to at least one of front end of line region 322 or back end of line region 324. Furthermore, as previously discussed in connection with FIG. 1, to maintain electrical isolation of the various components of backside capacitor 306, any suitable insulating material 326 (which may be the same as insulating material 118) may be arranged adjacent to respective portions of the plurality of through-silicon vias 312 and 314 traversing through the backside region of die 300.

Respective portions of dielectric material are disposed in between each of the metal traces to complete the structure of backside capacitor 302. As shown, dielectric layer 316 is disposed in between first metal traces 304 and second metal traces 306; another dielectric layer 318 is disposed in between second metal traces 306 and third metal traces 308; and another dielectric layer 320 is disposed in between third metal traces 308 and fourth metal traces 310.

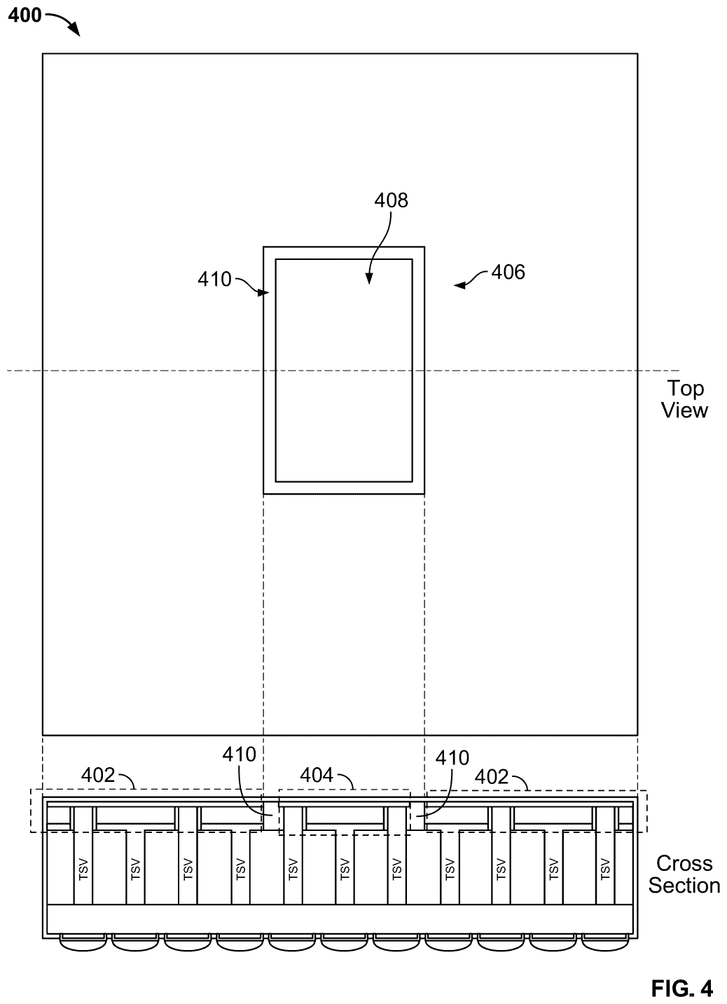

In some implementations, it is desired to provide respective decoupling capacitances (which are not electrically coupled to each other) to respective components of an integrated circuit. FIG. 4 shows an illustrative plan view of a power delivery network having global and local power networks, and an illustrative cross-sectional view of separate backside capacitors for the global and local power networks, in accordance with one implementation of the subject matter of this disclosure.

Die 400 includes first backside capacitor 402 and second backside capacitor 404. While first backside capacitor 402 and second backside capacitor 404 are both shown with two metal traces (e.g., similar to the depiction shown in FIG. 1), either capacitor may realize a similar structure to that depicted by backside capacitor 202, backside capacitor 302, or any other backside capacitor that is consistent with the subject matter of this disclosure.

First backside capacitor 402 may be separated from second backside capacitor 404 by insulting material 410 (which may correspond to insulating material 118). This separation electrically isolates first backside capacitor 402 from second backside capacitor 404, preventing any coupling of first power network 406 and second power network 408 (e.g., which could occur through a shared decoupling capacitor). In one implementation, first power network 406 corresponds to a global power network that is coupled to a supply voltage that is utilized by the majority of the circuitry of the ASIC that is fabricated into die 400, and second power network 408 corresponds to a local power network that is coupled to a supply voltage that is utilized by a portion of the ASIC that is not connected to the first power network 406.

First power network 406 and second power network 408 may deliver power to components of die 400 that are configured to perform different tasks. For example, first power network 406 may power a central processing unit, and second power network 408 may power a phase-locked loop configured to support the central processing unit (e.g., for clocking). First backside capacitor 402 may be aligned with circuitry of the global power network 406, and second backside capacitor 404 may be aligned with circuitry of the local power network 408. Thus, in an arrangement with multiple backside capacitors, each backside capacitor may be aligned with the integrated circuitry for which it provides the decoupling capacitance.

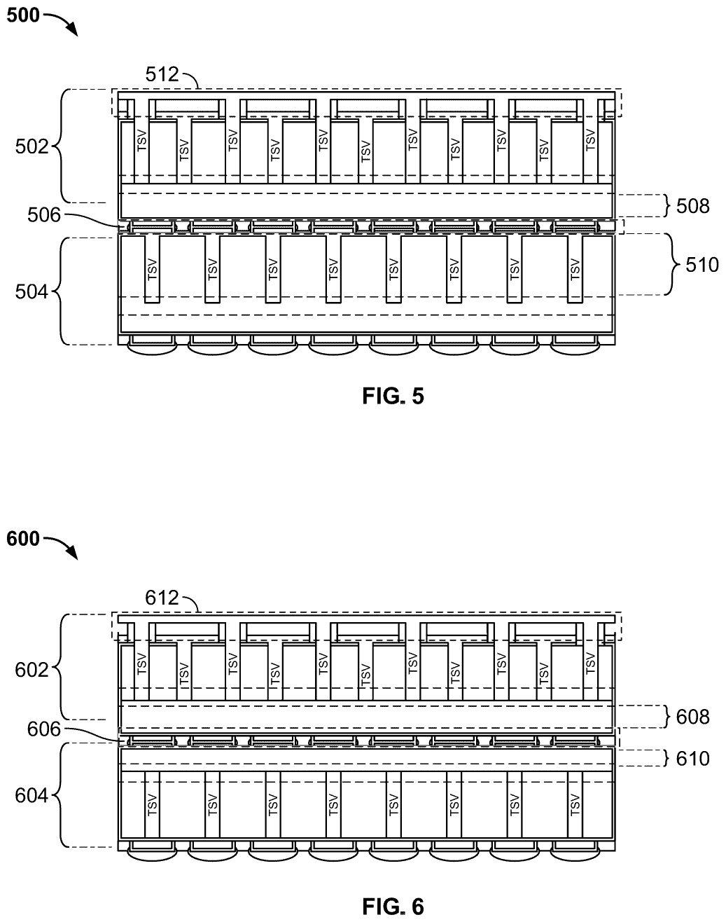

In some implementations, the backside capacitor of a first die may also provide a decoupling capacitance for a second die that is stacked upon the first die, as further described in connection with FIGS. 5-6. FIG. 5 is an illustrative cross-sectional view of a backside capacitor providing a decoupling capacitance for two dies stacked using face-to-back bonding, in accordance with one implementation of the subject matter of this disclosure.

Stacked dies 500 include first die 502 and second die 504. Though depicted similarly to die 100, first die 502 may correspond to any of dies 100, 200, or 300, or to any other die with a backside capacitor that is consistent with the subject matter of this disclosure. Though not explicitly shown, second die 504 may have its own backside capacitor (e.g., second die 504 may correspond to any of dies 100, 200, or 300) to provide additional decoupling capacitance; otherwise, second die 504 may be any suitable semiconductor device. First die 502 and second die 504 are coupled to each other by bond pad layer 506.

First die 502 and second die 504 are stacked using face-to-back bonding. As such, while not visually apparent in FIG. 5, interconnects embedded in back end of line region 508 of first die 502 are coupled to backside region 510 of second die 504. These interconnects couple the decoupling capacitance of backside capacitor 512 to components of second die 504 (e.g., to active silicon devices of an ASIC fabricated into second die 504). Backside capacitor 512 may correspond to any of backside capacitors 102, 202, or 302.

An alternative to face-to-back bonding is to stack dies using face-to-face bonding. FIG. 6 is an illustrative cross-sectional view of a backside capacitor providing a decoupling capacitance for two dies stacked using face-to-face bonding, in accordance with one implementation of the subject matter of this disclosure.

Stacked dies 600 include first die 602 and second die 604. Though depicted similarly to die 100, first die 602 may correspond to any of dies 100, 200, or 300, or to any other die with a backside capacitor that is consistent with the subject matter of this disclosure. Though not explicitly shown, second die 604 may have its own backside capacitor (e.g., second die 604 may correspond to any of dies 100, 200, or 300) to provide additional decoupling capacitance; otherwise, second die 604 may be any suitable semiconductor device. First die 602 and second die 604 are coupled to each other by bond pond layer 606.

While not visually apparent in FIG. 6, interconnects embedded in back end of line region 608 are coupled to portions of back end of line region 610. These interconnects couple the decoupling capacitance of backside capacitor 612 to components of second die 604 (e.g., to active silicon devices of an ASIC fabricated into second die 604).

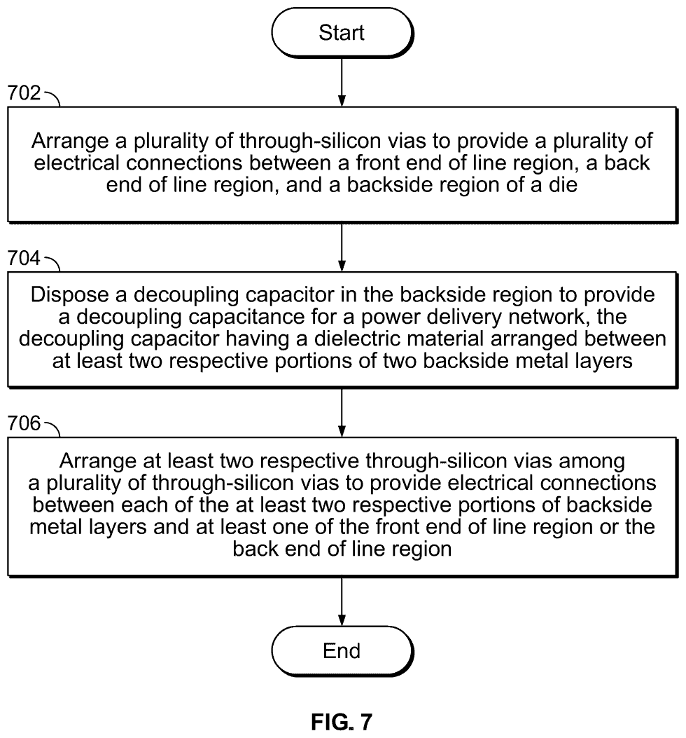

FIG. 7 is a flow diagram illustrating method 700 for reducing impact of noise caused by a power delivery network supplying power to a die having an integrated circuit, in accordance with one implementation of the subject matter of this disclosure.

At 702, a plurality of through-silicon vias are arranged to provide a plurality of electrical connections between a front end of line region, a back end of line region, and a backside region of a die. For example, as described in connection with FIG. 1, through-silicon vias 116 provide electrical connections between backside region 110, front end of line region 112, and back end of line region 114.

At 704, a decoupling capacitor is disposed in the backside region of the die to provide a decoupling capacitance for a power delivery network. The decoupling capacitor has a dielectric material arranged between at least two respective portions of two backside metal traces. In some implementations, e.g., as described in connection with FIGS. 2-3, the dielectric material may be interdigitated between at least two respective portions of two backside metal traces to provide an increased decoupling capacitance.

At 706, at least two respective through-silicon vias among the plurality of through-silicon vias are arranged to provide electrical connections between each of the at least two respective portions of backside metal traces and at least one of the front end of line region or the back end of line region. For example, as described in connection with FIG. 1, through-silicon vias 116 provide electrical connections between metal traces 104 and 106 to front end of line region 112 and back end of line region 114.

Thus it is seen that a method for reducing impact of noise caused by a power delivery network supplying power to a die having an integrated circuit has been provided.

As used herein and in the claims which follow, the construction “one of A and B” shall mean “A or B.”

It is noted that the foregoing is only illustrative of the principles of the invention, and that the invention can be practiced by other than the described implementations, which are presented for purposes of illustration and not of limitation, and the present invention is limited only by the claims which follow.

What is claimed is:

1. A die having an integrated circuit with backside decoupling capacitance that reduces impact of noise caused by a power delivery network supplying power to the integrated circuit, the die having a front end of line region comprising active silicon devices, a back end of line region, and a backside region opposite the back end of line region, the integrated circuit comprising:
a power delivery network spanning the front end of line region, the back end of line region, and the backside region, the power delivery network:
comprising a plurality of through-silicon vias disposed perpendicular to the plurality of lateral metal traces and configured to provide electrical connections between the front end of line region, the back end of line region, and the backside region, and
being electrically coupled to a plurality of lateral metal traces comprising back end of line metal traces disposed in the back end of line region and backside metal traces disposed in the backside region; and
a decoupling capacitor disposed in the backside region to provide the backside decoupling capacitance, the decoupling capacitor comprising:
at least two respective portions of at least two of the backside metal traces, each of the at least two respective portions being electrically coupled to at least one of the front end of line region or the back end of line region by at least two respective through-silicon vias among the plurality of through-silicon vias, and
a dielectric material arranged between the at least two respective portions of the backside metal traces.

2. The die of claim 1, wherein the dielectric material and the at least two respective portions of the at least two of the backside metal traces are interdigitated to increase a contact surface area between the dielectric material and the at least two respective portions of the at least two of the backside metal traces, wherein the increased contact surface area increases capacitance of the decoupling capacitor.

3. The die of claim 1, wherein the back end of line region comprises a plurality of interconnects which electrically couple the integrated circuit to a redistribution layer or a bond pad layer.

4. The die of claim 3, wherein at least one interconnect of the plurality of interconnects is further electrically coupled to a second backside region of a second die to reduce impact of noise caused by a second power delivery network of the second die.

5. The die of claim 3, wherein at least one interconnect of the plurality of interconnects is further electrically coupled to a second back end of line region of a second die to reduce impact of noise caused by a second power delivery network of the second die.

6. The die of claim 1, wherein:
the backside metal traces comprise first metal traces, second metal traces stacked on top of the first metal traces, third metal traces stacked on top of the second metal traces, and fourth metal traces stacked on top of the third metal traces; and
respective portions of the first metal traces, the second metal traces, the third metal traces, and the fourth metal traces are interdigitated with each other.

7. The die of claim 6, wherein the dielectric material comprises:
a first layer disposed in between respective interdigitated portions of the first metal traces and the second metal traces;
a second layer disposed in between respective interdigitated portions of the second metal traces and the third metal traces; and
a third layer disposed in between respective interdigitated portions of the third metal traces and the fourth metal traces.

8. The die of claim 6, wherein:
at least one first through-silicon via among the plurality of through-silicon vias is coupled to the first metal traces and to the third metal traces to form a first plate of the decoupling capacitor; and
at least one second through-silicon via among the plurality of through-silicon vias is coupled to the second metal traces and to the fourth metal traces to form a second plate of the decoupling capacitor.

9. The die of claim 1, wherein:
the decoupling capacitor is a first decoupling capacitor, the die further comprising a second decoupling capacitor disposed in the backside region.

10. The die of claim 9, wherein:
the first decoupling capacitor is coupled to a global power network, the global power network coupled to a first supply voltage that is utilized by a majority of circuitry of the integrated circuit; and
the second decoupling capacitor is coupled to a local power network, the local power network coupled to a second supply voltage that is utilized by at least one circuit in the integrated circuit that is not coupled to the first supply voltage.

11. A method for reducing impact of noise caused by a power delivery network supplying power to a die having an integrated circuit, the die having a front end of line region comprising active silicon devices, a back end of line region, and a backside region opposite the back end of line region, the method comprising:
arranging a plurality of through-silicon vias to provide a plurality of electrical connections between the front end of line region, the back end of line region, and the backside region;
disposing a decoupling capacitor in the backside region to provide a decoupling capacitance for the power delivery network, the decoupling capacitor having a dielectric material arranged between at least two respective portions of two backside metal traces; and
arranging at least two respective through-silicon vias among the plurality of through-silicon vias to provide electrical connections between each of the at least two respective portions of the two backside metal traces and at least one of the front end of line region or the back end of line region.

12. The method of claim 11, further comprising interdigitating the dielectric material and the at least two respective portions of the at least two of the backside metal traces to increase a contact surface area between the dielectric material and the at least two respective portions of the at least two of the backside metal traces, wherein the increased contact surface area increases capacitance of the decoupling capacitor.

13. The method of claim 11, wherein the back end of line region comprises a plurality of interconnects, the method further comprising:
electrically coupling the integrated circuit to a redistribution layer or a bond pad layer using the plurality of interconnects.

14. The method of claim 13, further comprising:
electrically coupling a second backside region of a second die to at least one interconnect of the plurality of interconnects to reduce impact of noise caused by a second power delivery network of the second die.

15. The method of claim 13, further comprising:
electrically coupling a second back end of line region of a second die to at least one interconnect of the plurality of interconnects to reduce impact of noise caused by a second power delivery network of the second die.

16. The method of claim 11, wherein the backside metal traces comprise first metal traces, second metal traces stacked on top of the first metal traces, third metal traces stacked on top of the second metal traces, and fourth metal traces stacked on top of the third metal traces, the method further comprising:
interdigitating respective portions of the first metal traces, the second metal traces, the third metal traces, and the fourth metal traces with each other.

17. The method of claim 16, further comprising:
disposing a first layer of dielectric material in between respective interdigitated portions of the first metal traces and the second metal traces;
disposing a second layer of dielectric material in between respective interdigitated portions of the second metal traces and the third metal traces; and
disposing a third layer of dielectric material in between respective interdigitated portions of the third metal traces and the fourth metal traces.

18. The method of claim 16, further comprising:
electrically coupling at least one first through-silicon via among the plurality of through-silicon vias to the first metal traces and to the third metal traces to form a first plate of the decoupling capacitor; and
electrically coupling at least one second through-silicon via among the plurality of through-silicon vias to the second metal traces and to the fourth metal traces to form a second plate of the decoupling capacitor.

19. The method of claim 11, wherein the decoupling capacitor is a first decoupling capacitor, the die further comprising a second decoupling capacitor disposed in the backside region, the method further comprising:
electrically coupling the first decoupling capacitor a global power network;
electrically coupling the global power network to a first supply voltage that is utilized by a majority of circuitry of the integrated circuit;
electrically coupling the second decoupling capacitor to a local power network; and
electrically coupling the local power network to a second supply voltage that is utilized by at least one circuit in the integrated circuit that is not coupled to the first supply voltage.

20. A die having a back end of line region, a front end of line region, a backside region opposite the back end of line region, a power delivery network supplying power to the die, and a backside capacitor configured to reduce impact of noise caused by the power delivery network, the backside capacitor comprising:
at least two respective portions of at least two backside metal traces disposed in the backside region, and
a dielectric material disposed in between the at least two respective portions of the at least two backside metal traces; wherein:
each of the at least two respective portions of the at least two backside metal traces are electrically coupled, by at least one respective through-silicon via, to the front end of line region to reduce the impact of the noise caused by the power delivery network on active silicon devices of the front end of line region.
